(19) United States
(12) Patent Application Publication
(10) Pub. No.: US 2026/0045310 A1
(43) Pub. Date: Feb. 12, 2026

(54) MEMORY DEVICE AND OPERATION METHOD THEREOF, AND MEMORY SYSTEM

(71) Applicant: YANGTZE MEMORY TECHNOLOGIES CO., LTD., Wuhan (CN)

(72) Inventors: Yuanyuan MIN, Wuhan (CN); Lei GUAN, Wuhan (CN); HongTao LIU, Wuhan (CN)

(21) Appl. No.: 19/012,331

(22) Filed: Jan. 7, 2025

(30) Foreign Application Priority Data
Aug. 12, 2024 (CN) 2024111051212

(51) Int. Cl. G11C 16/34; G11C 16/08; G11C 16/26

(52) U.S. Cl. CPC G11C 16/3418; G11C 16/08; G11C 16/26

(57) ABSTRACT

The present application provides a memory device and an operation method thereof, and a memory system. The memory device includes a memory array and a peripheral circuit. The peripheral circuit is coupled with the memory array, and is configured to: apply a read voltage to a selected first word line of the plurality of word lines; apply a first pass voltage to an unselected second word line of the plurality of word lines in response to determining that a working temperature is a first temperature; and apply a second pass voltage to the second word line in response to determining that the working temperature is a second temperature, wherein the first temperature is greater than the second temperature, and the first pass voltage is less than the second pass voltage.

### CROSS-REFERENCE TO RELATED APPLICATIONS

The present application claims priority to Chinese Patent Application No. 2024111051212, which was filed Aug. 12, 2024, and is hereby incorporated herein by reference in its entirety.

### TECHNICAL FIELD

The present application relates to the technical field of semiconductors, and more particularly to a memory device, a memory system, and a method of operating a memory device.

### BACKGROUND

A memory device (such as a NAND memory device) is capable of retaining data stored therein after power-off, and is widely applied in computers, cellphones, smart phones, personal digital assistants, and other electronic apparatus systems.

### SUMMARY

In a first aspect, some examples of the present application provide a memory device. The memory device comprises a memory array and a peripheral circuit. The memory array comprises a plurality of memory cells and a plurality of word lines, wherein the word line is coupled with the memory cell. The peripheral circuit is coupled with the memory array, and is configured to: apply a read voltage to a selected first word line of the plurality of word lines; apply a first pass voltage to an unselected second word line of the plurality of word lines in response to determining that a working temperature is a first temperature; and apply a second pass voltage to the second word line in response to determining that the working temperature is a second temperature, wherein the first temperature is greater than the second temperature, and the first pass voltage is less than the second pass voltage.

In an example implementation, the peripheral circuit is further configured to: determine the first pass voltage according to the first temperature in response to determining that the working temperature is the first temperature, and apply the first pass voltage to the second word line; and determine the second pass voltage according to the second temperature in response to determining that the working temperature is the second temperature, and apply the second pass voltage to the second word line.

In an example implementation, the first temperature is greater than a preset temperature, and the second temperature is less than the preset temperature.

In an example implementation, the first pass voltage decreases as the first temperature increases.

In an example implementation, the first pass voltage decreases linearly at a first slope as the first temperature increases.

In an example implementation, the first pass voltage decreases non-linearly as the first temperature increases.

In an example implementation, the second pass voltage decreases as the second temperature increases.

In an example implementation, the second pass voltage decreases at a second slope as the second temperature increases, and the first slope is different from the second slope.

In an example implementation, the memory array further comprises a plurality of bit lines and a source line, wherein the bit line is coupled with the memory cell, and the source line is coupled with the memory cell. The peripheral circuit is further configured to: apply a first bias voltage to the selected bit line of the plurality of bit lines; and apply a second bias voltage to the source line, wherein the first bias voltage is different from the second bias voltage.

In an example implementation, the read voltage is less than the first pass voltage, and the read voltage is less than the second pass voltage.

In a second aspect, some examples of the present application provide a memory system. The memory system comprises a memory device and a memory controller. The memory device may be implemented as the memory device mentioned in any of the implementations above. The memory controller is coupled with the memory device and to control the memory device to store data.

In a third aspect, some examples of the present application provide a method of operating a memory device. The memory device comprises a plurality of memory cells and a plurality of word lines, wherein a memory cell is coupled with the word line. The operation method comprises: applying a read voltage to a selected first word line of the plurality of word lines; applying a first pass voltage to an unselected second word line of the plurality of word lines in response to determining that a working temperature is a first temperature; and applying a second pass voltage to the second word line in response to determining that the working temperature is a second temperature, wherein the first temperature is greater than the second temperature, and the first pass voltage is less than the second pass voltage.

In an example implementation, applying the first pass voltage to the unselected second word line of the plurality of word lines in response to determining that the working temperature is the first temperature comprises: determining the first pass voltage according to the first temperature in response to determining that the working temperature is the first temperature, and applying the first pass voltage to the second word line; wherein applying the second pass voltage to the second word line in response to determining that the working temperature is the second temperature comprises: determining the second pass voltage according to the second temperature in response to determining that the working temperature is the second temperature, and applying the second pass voltage to the second word line.

In an example implementation, the first temperature is greater than a preset temperature, and the second temperature is less than the preset temperature.

In an example implementation, the first pass voltage decreases as the first temperature increases.

In an example implementation, the first pass voltage decreases linearly at a first slope as the first temperature increases.

In an example implementation, the first pass voltage decreases non-linearly as the first temperature increases.

In an example implementation, the second pass voltage decreases as the second temperature increases.

In an example implementation, the second pass voltage decreases linearly at a second slope as the second temperature increases, and the first slope is different from the second slope.

In an example implementation, the memory device further comprises a plurality of bit lines and a source line, wherein the bit line is coupled with the memory cell, and the source line is coupled with the memory cell. The operation method further comprises: applying a first bias voltage to a selected bit line of the plurality of bit lines; and applying a second bias voltage to the source line, wherein the first bias voltage is different from the second bias voltage.

In an example implementation, the read voltage is less than the first pass voltage, and the read voltage is less than the second pass voltage.

### BRIEF DESCRIPTION OF THE DRAWINGS

Other features, purposes and advantages of the present application will become more apparent by reading the detailed description of non-limiting examples made by reference to the following drawings, in which:

FIG. 1 is a schematic block diagram of a memory device provided by examples of the present application;

FIG. 2 is a schematic circuit diagram of a memory block in a memory device provided by examples of the present application;

FIG. 3 is a schematic distribution diagram of threshold voltages of a memory cell in an xLC mode provided by examples of the present application;

FIG. 4 is a schematic distribution diagram of threshold voltages of a memory cell after a drift in an xLC mode provided by examples of the present application;

FIG. 5 is a schematic diagram of a selected word line and unselected word lines of a memory string in a memory device during a read operation provided by examples of the present application;

FIGS. 6A-6G are schematic diagrams of curves between temperatures and pass voltages provided by some examples of the present application;

FIG. 7 is a schematic block diagram of a system having a memory system provided by examples of the present application;

FIGS. 8A and 8B are schematic block diagrams of a memory system provided by examples of the present application; and

FIG. 9 is a flow diagram of a method of operating a memory device provided by examples of the present application.

### DETAILED DESCRIPTION

In order to better understand the present application, various aspects of the present application will be described in more detail with reference to the drawings. It is understood that, these detailed descriptions are only descriptions of example implementations of the present application, and are not intended to limit the scope of the present application in any manner. Like reference numbers denote like elements throughout the specification. The expression “and/or” includes any or all combinations of one or more of listed associated items.

It is to be noted that, in the specification, the expressions, such as first, second, third and the like, are only used to distinguish one feature from another feature, instead of representing any limitation to the features, particularly instead of representing any sequential order. Thus, without departing from the teaching of the present application, a first word line discussed in the present application may be also called a second word line, or vice versa.

For ease of illustration, the thicknesses, sizes and shapes of components have been slightly adjusted in the drawings. The drawings are merely exemplary and are not drawn to scale precisely. As used herein, terms, “approximately”, “about”, and the like, are used to represent approximation, instead of representing a degree, and are intended to describe inherent deviations in measured values or calculated values as recognized by those of ordinary skill in the art.

It should be also understood that, expressions, such as “comprise”, “comprising”, “have”, “include”, and/or “including”, etc., are open-ended expressions, rather than close-ended expressions in the specification. They represent the existence of the stated features, elements and/or components, but the existence of one or more other features, elements, components and/or combinations thereof is not precluded. Moreover, the expression, such as “at least one of . . . ”, appearing before a list of listed features, modifies the whole list of features, rather than an individual element therein. Furthermore, “may” is used to represent “one or more implementations of the present application” when describing the implementations of the present application. Moreover, the term “exemplary” is intended to refer to an example or illustration.

Unless otherwise defined, all phrases (including engineering terms and technical terms) as used herein have the same meanings as those generally understood by those of ordinary skill in the art to which the present application pertains. It is to be further understood that, terms as defined in common dictionaries should be interpreted as having a meaning that is consistent with their meaning in the context of the related art, and should not be interpreted in an idealized or overly formal sense unless otherwise stated expressly in the present application.

It is to be noted that, implementations and features in the implementations of the present application may be mutually combined in the case of no conflicts. Additionally, unless otherwise defined explicitly or conflicting with the context, specific operations included in a method as set forth in the present application are not necessarily limited to an order as set forth, but may be carried out in any order or in parallel.

The present application will now be described below in detail with reference to the drawings and the examples.

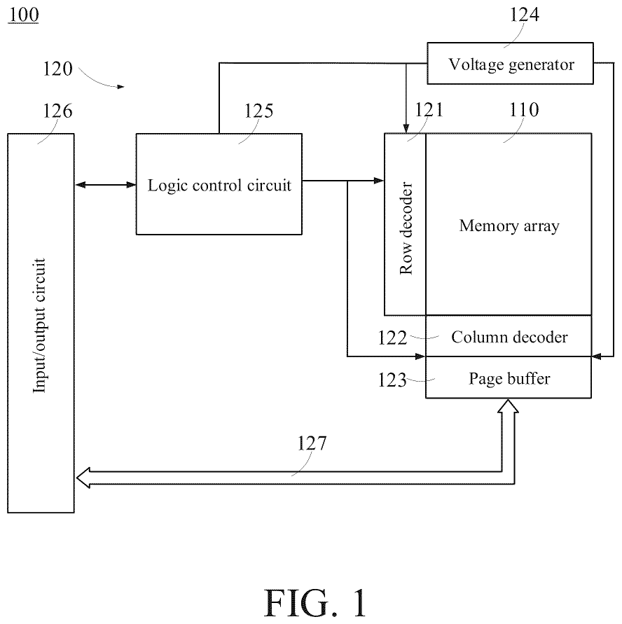

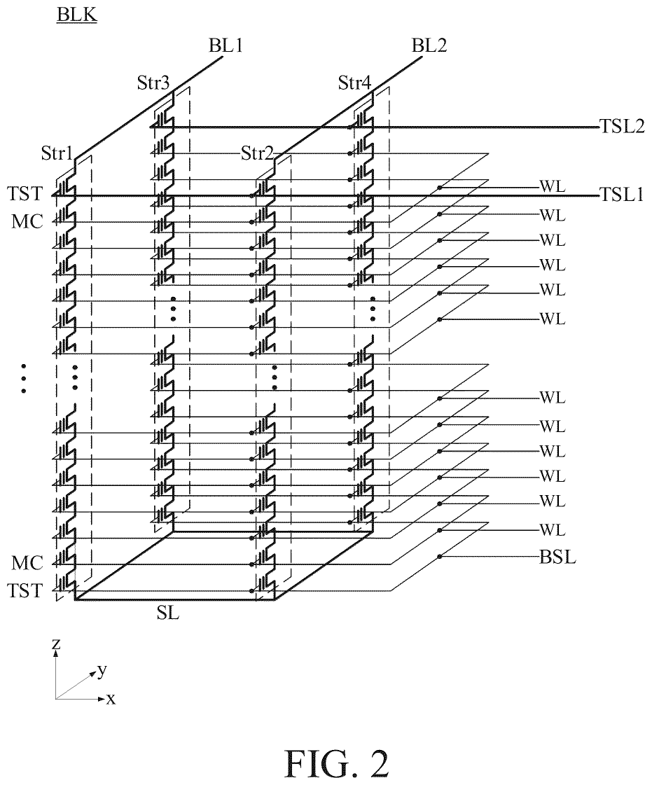

Some examples of the present application provide a memory device. FIG. 1 is a schematic block diagram of a memory device provided by examples of the present application. FIG. 2 is a schematic circuit diagram of a memory block in a memory device provided by examples of the present application.

As shown in FIG. 1, the memory device 100 may comprise a memory array 110 and a peripheral circuit 120. For example, the memory array 110 may comprise one or more dies (Die/LUN) which may be basic units for receiving and executing, for example, a program command and a read command. Each of the dies may comprise one or more memory planes, and each of the planes may comprise one or more memory blocks. For example, the memory array 110 may be a NAND memory array.

In some implementations, as shown in FIG. 2, the memory block BLK may comprise a plurality of memory strings Str, such as Str1, Str2, Str3, and Str4. The plurality of memory strings Str1-Str4 may be arranged in a two-dimensional array on an xy plane. Each of the plurality of memory strings Str1-Str4 may extend along a z direction and may comprise a top select transistor TST, a memory cell MC, and a bottom select transistor BST which are connected with each other. It is to be noted that, the number of the top select transistor TST, the bottom select transistor BST, and the memory cell MC in each of the plurality of memory strings Str1-Str4 is only an example, and the number of the above devices is not specifically limited in the present application. Furthermore, provision of the top select transistor TST or the bottom select transistor BST may also be omitted. For example, each of the plurality of memory strings Str1-Str4 may not comprise one of the top select transistor TST and the bottom select transistor BST.

In some implementations, the memory cell MC may be a floating gate field effect transistor or a charge trapping field effect transistor. The top select transistor TST may be a conventional field effect transistor or of the same type as the memory cell MC. Similarly, the bottom select transistor BST may be a conventional field effect transistor or of the same type as the memory cell MC.

In some implementations, the plurality of memory strings Str1-Str4 in one memory block BLK may be connected with a source line SL. For example, an active terminal (e.g., a source terminal or a drain terminal) of the bottom select transistor BST located at an end of each of the plurality of memory strings Str1-Str4 may be connected to the source line SL.

In some implementations, a control terminal (e.g., a gate terminal) of the memory cell MC located at the same height or a similar height from the source line SL in each of the plurality of memory strings Str1-Str4 may be connected to the same word line WL.

In some implementations, a control terminal (e.g., a gate terminal) of the top select transistor TST located at the same height or a similar height from the source line SL in each of the plurality of memory strings Str1 and Str2 arranged in an x direction may be connected to the same top select line TSL1. Similarly, a control terminal (e.g., a gate terminal) of the top select transistor TST3 located at the same height or a similar height from the source line SL in each of the memory strings Str3 and Str4 arranged in the x direction may be connected to the same another top select line TSL2.

In some implementations, a control terminal (e.g., a gate terminal) of the bottom select transistor BST located at the same height or a similar height from the source line SL in each of the plurality of memory strings Str1-Str4 may be connected to the same bottom select line BSL. In some other implementations, a control terminal (e.g., a gate terminal) of the bottom select transistor BST located at the same height or a similar height from the source line SL in each of the plurality of memory strings Str1 and Str2 arranged in the x direction may be connected to the same top select line BSL1 (not shown). Similarly, a control terminal (e.g., a gate terminal) of the bottom select transistor BST3 located at the same height or a similar height from the source line SL in each of the memory strings Str3 and Str4 arranged in the x direction may be connected to the same another bottom select line BSL2 (not shown).

In some implementations, an active terminal (e.g., a source terminal or a drain terminal) of the top select transistor TST located at the same height or a similar height from the source line SL in each of the plurality of memory strings Str1 and Str3 arranged in a y direction may be connected to the same bit line BL1. Similarly, an active terminal (e.g., a drain terminal or a source terminal) of the top select transistor TST located at the same height or a similar height from the source line SL in each of the plurality of memory strings Str2 and Str4 arranged in the y direction may be connected to the same another bit line BL2.

In some implementations, as shown in FIGS. 1 and 2, the peripheral circuit 120 may comprise any suitable digital, analog, and/or hybrid-signal functional circuit for supporting functions of the memory array 110, such as a row decoder (or referred to as a word line driver) 121, a column decoder (or referred to as a bit line driver) 122, a page buffer (or referred to as a sense amplifier) 123, a voltage generator 124, a logic control circuit 125, an input/output (I/O) circuit 126, and a data bus 127. The memory cell MC may be coupled with the row decoder 121 via a word line WL. The memory cell MC may be coupled with the column decoder 122 via a bit line BL. For example, the functional circuit described above may comprise one or more of any active or passive devices (e.g., a transistor, a diode, a resistor, or a capacitor).

The row decoder 121 may be configured to select one memory block in the memory array 110 and further select a page in the memory block in response to a control signal from the logic control circuit 125. The row decoder 121 may be configured to transmit a voltage supplied from the voltage generator 124 to the word line WL. For example, during performance of a read operation, the row decoder 121 may be configured to transmit a read voltage V_{read} to a selected word line WL and transmit a pass voltage Vₚₐₛₛ to an unselected word line WL.

The column decoder 122 may be configured to select a column of memory strings in the memory array 110 in response to the control signal from the logic control circuit 125. The column decoder 122 may be configured to transmit the voltage supplied from the voltage generator 124 to the bit line BL. For example, during the execution of the read operation, the column decoder 122 may be configured to transmit a first bias voltage V_{bias1} to a selected bit line BL and transmit an inhibit voltage V_{inhibit} to an unselected bit line BL.

The page buffer 123 may be configured to read data from the memory array 110 or program (write) data to the memory array 110 in response to the control signal from the logic control circuit 125. In one example, the page buffer 123 may store data to be programmed to one page of the memory array 110. In another example, the page buffer 123 may sense a low power signal of data stored in the memory cell MC of the memory array 110 during the execution of the read operation and amplify a small voltage swing to a recognizable logic level.

The voltage generator 124 may be configured to generate various voltages to be supplied to the memory array 110, such as the read voltage V_{read}, the pass voltage Vₚₐₛₛ, the first bias voltage V_{bias1}, and a second bias voltage V_{bias2}, etc., in response to the control signal from the logic control circuit 125.

The logic control circuit 125 may comprise one or more logic control units, and the logic control unit may serve as a software module and/or a firmware module running on some of processors (e.g., a microcontroller unit (MCU)) of the logic control circuit 125, or may be a hardware module of a finite state machine (FSM), such as an integrated circuit (e.g., an application specific IC (ASIC), and a field programmable gate array (FPGA), etc.), or may be a combination of a software module, a firmware module, and a hardware module.

The input/output circuit 126 may transmit data to and from the page buffer 123 via the data bus 127 and transmit, for example, an address ADDR and/or a command CMD to the logic control circuit 125. For example, the logic control circuit 125 may be configured to control the row decoder 121, the column decoder 122, and the page buffer 123 in response to the command CMD transmitted from the input/output circuit 126.

In the NAND memory device, the memory cell may be configured to operate in a single-level cell (SLC) mode. In this example, the memory cell may be in an erased state ER or a programmed state P1. For example, initially, the memory cell may be reset to the erased state ER as a logic “1” by implementing a negative voltage difference between a word line (e.g., a control terminal of the memory cell) coupled with the memory cell and a source line, thereby enabling charge trapped in a storage layer of the memory cell to be eliminated. For example, the negative voltage difference may be induced by grounding the word line (e.g., the control terminal of the memory cell) coupled with the memory cell and applying a high positive voltage to the source line. In the erased state ER, a threshold voltage Vₜₕ of the memory cell may be reset to the lowest value. During performance of a program operation, a program voltage V_{pgm} may be applied to the above-mentioned word line such that charge (e.g., electrons) can be injected into the storage layer of the memory cell, thereby raising the threshold voltage Vₜₕ of the memory cell, and the memory cell may be programmed to the programmed state P1.

In the NAND memory device, the memory cell may be further configured to operate in a multi-level cell (MLC) mode, a triple-level cell (TLC) mode, a quad-level cell (QLC) or a combination of thereof. In the SLC mode, one memory cell stores 1 bit and has two logic states, e.g., states ER and P1. In the MLC mode, one memory cell stores 2 bits and has four states, e.g., states ER, P1, P2, and P3. In the TLC mode, one memory cell stores 3 bits and has eight states, e.g., states ER and P1-P7. In the QLC mode, one memory cell stores 4 bits and has 16 states, e.g., states ER and P1-P15. In general, one memory cell in the xLC mode may have 2ⁿ states and may store n bits of data, wherein n is an integer. For example, n equals 1, 2, 3, and 4 respectively for the SLC, MLC, TLC, and QLC modes.

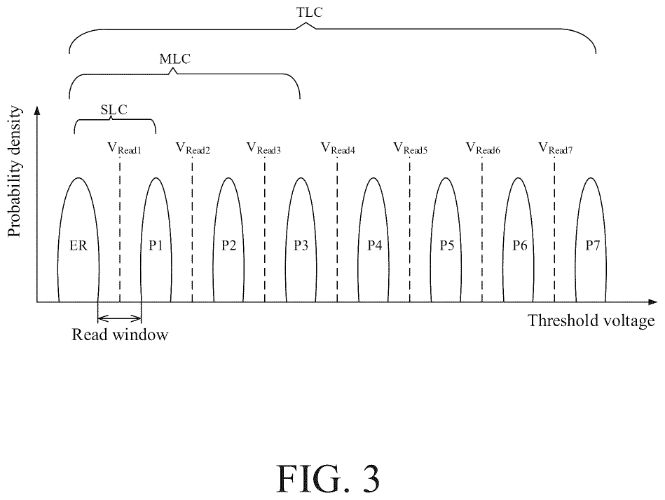

FIG. 3 is a schematic distribution diagram of threshold voltages of a memory cell in an xLC mode provided by examples of the present application. Due to various reasons of variation, each state of the memory cell comprises a certain range of threshold voltages Vₜₕ. Distribution of the threshold voltage Vₜₕ of each state may be represented by a probability density. For example, the 2ⁿ states in the xLC mode may be programmed from the state ER to one of the states P1−P(2ⁿ−1). As shown in FIG. 3, from the state ER to the state P(2ⁿ−1), the threshold voltage Vₜₕ of the memory cell increases. Thus, the state ER is also referred to as the lowest state, and the state P(2ⁿ−1) is also referred to as the highest state. The higher state has a higher threshold voltage, and the lower state has a lower threshold voltage.

As shown in FIG. 3, the state of the memory cell may be determined by comparing the threshold voltage Vₜₕ of the memory cell with one or more read voltages V_{Read} (e.g., one of V_{Read1}-V_{Read7}), such that the state or data stored in the memory cell may be determined. The read voltage V_{Read} may be selected to lie within a read window (also referred to as a sense margin) between two adjacent states, e.g., between the highest possible threshold voltage for the lower state and the lowest possible threshold voltage for the higher state. For example, in order to verify whether a target memory cell is in the state ER, the read voltage V_{Read1} may be used. If the target memory cell is in the state ER, the threshold voltage Vₜₕ of the target memory cell is lower than the read voltage V_{Read1}, and the target memory cell may be turned on and a conductive pathway may be formed in a channel. If the target memory cell is in any one of the states P1-P7, the threshold voltage Vₜₕ of the target memory cell is higher than the read voltage V_{Read1}, and the target memory cell may be turned off. The threshold voltage Vₜₕ or the state of the target memory cell can be determined by measuring or sensing a current passing through the target memory cell at a bit line coupled to the memory string where the target memory cell is located.

In order to determine the two states ER and P1 stored in the SLC mode, the voltage V_{Read1} needs to be read. In order to determine the four states ER and P1-P3 in the MLC mode, read voltages V_{Read1}, V_{Read2}, and V_{Read3} may be used. In order to determine the eight states ER and P1-P7 in the TLC mode, read voltages V_{Read1}-V_{Read7} may be used. For example, in the TLC mode, the threshold voltage for the state ER is lower than V_{Read1} and the threshold voltage for the state P7 is higher than V_{Read7}. The threshold voltage for the state P1 is between V_{Read1} and V_{Read2}, and the states P2-P6 can be similarly determined. Similarly, in the QLC mode, 16 states (ER and P1-P15) may be verified with 15 read voltages. In order to verify the 2ⁿ states in the xLC mode, 2ⁿ−1 read voltages may be used.

During the execution of the read operation, for the target memory cell (e.g., a selected memory cell) in a memory string, a read voltage needs to be applied to a word line (e.g., the selected word line) coupled with the target memory cell. For non-target memory cells (e.g., unselected memory cells) other than the target memory cell in the memory string, pass voltages need to be applied to the word lines (e.g., unselected word lines) coupled to each of the non-target memory cells respectively. The pass voltage may be any suitable voltage higher than the threshold voltage Vₜₕ of the highest state of the memory cell (e.g., the state P(2ⁿ−1) in the xLC mode) to ensure that all non-target memory cells in the memory string are turned on during the execution of the read operation.

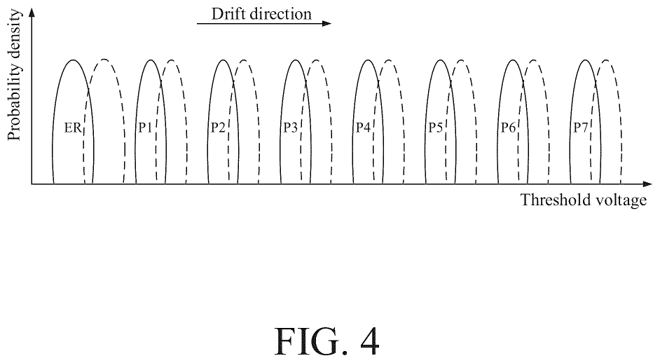

After the read operation, the pass voltage will cause a drift in the threshold voltage of the unselected memory cell. FIG. 4 is a schematic distribution diagram of threshold voltages of a memory cell after a drift in an xLC mode provided by examples of the present application. For example, as shown in FIG. 4, in the TLC mode, the threshold voltages of the unselected memory cells drift to the right as a whole, e.g., the threshold voltages of the unselected memory cells in the erased state ER drift along a direction (e.g., to the right) of an arrow in the figure. The threshold voltages of the unselected memory cells in the programmed state (e.g., any one of the programmed states P1-P7) drift along the direction (e.g., to the right) of the arrow in the figure. The drift in the threshold voltages of the unselected memory cells in the erased state ER is particularly obvious. The drift in the threshold voltages of the unselected memory cells will cause a read error. For example, during execution of the subsequent read operation, when the memory cell after the drift serves as the selected memory cell, the read error may be caused if the original read voltage is still applied to perform the read operation because the threshold voltage distribution of the selected memory cell changes.

Degrees of read disturbance (e.g., drift to the right) are different when the unselected memory cells work at different temperatures. For example, the unselected memory cells may work at different temperatures, e.g., the unselected memory cells may work at a low temperature (e.g., −25°C) as well as at a high temperature (e.g., 85° C.), and the sensitivity of the read disturbance is different at different temperatures. At different working temperatures, the unselected memory cells work by applying the same pass voltage to the word lines coupled to the unselected memory cells.

The higher the temperature is, the more serious the read disturbance is, such that the probability of causing the read error increases. Furthermore, the working of the unselected memory cell at high and low temperatures during a current read operation will result in a difference in a sense margin (a read window) for the selected memory cell during a subsequent read operation, thereby affecting read accuracy. The sense margin is larger when the working temperature is higher (e.g., 85° C.), and is smaller when the working temperature is lower (e.g., −25°C), thereby the difference in sense margin is formed between the high and low temperatures. The reason for the difference in sense margin between the high and low temperatures may be some intrinsic problems of memory cells, noise, and related processes when the memory cells are manufactured.

In the examples of the present application, circuit configuration of the peripheral circuit is adjusted, e.g., different pass voltages are applied to the word lines coupled to the unselected memory cells during the execution of the read operation at different working temperatures. When the working temperature is higher, a lower pass voltage is applied, and when the working temperature is lower, a higher pass voltage is applied. For example, a higher working temperature corresponds to a lower pass voltage, and a lower working temperature corresponds to a higher pass voltage. When the working temperature is higher, the lower pass voltage is applied correspondingly to enable to greatly reduce high temperature read interference and ensure that the sense margin will not be excessively reduced. When the working temperature is lower, the higher pass voltage is applied correspondingly, which can reduce the difference in sense margin between the high and low temperatures, ensure the read accuracy, and have no obvious influence on the read disturbance.

It should be noted that the lower pass voltage applied should be such that the unselected memory cells can be turned on during the read operation. For example, as shown in FIG. 4, the lower pass voltage needs to be greater than the maximum threshold voltage value in the range of threshold voltages for the programmed state P7 after the maximum drift. In the examples of the present application, the lower pass voltage and the higher pass voltage are relative concepts. For example, the maximum threshold voltage value in the threshold voltage range of the programmed state P7 after the maximum drift is taken as a reference voltage, the lower pass voltage means that a difference between the pass voltage and the reference voltage is small, and the higher pass voltage means that a difference between the pass voltage and the reference voltage is large, that is, a voltage value of the higher pass voltage is larger than a voltage value of the lower pass voltage.

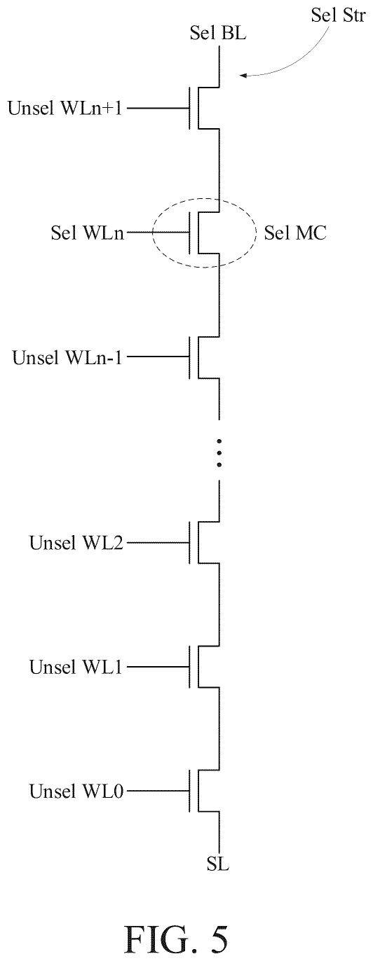

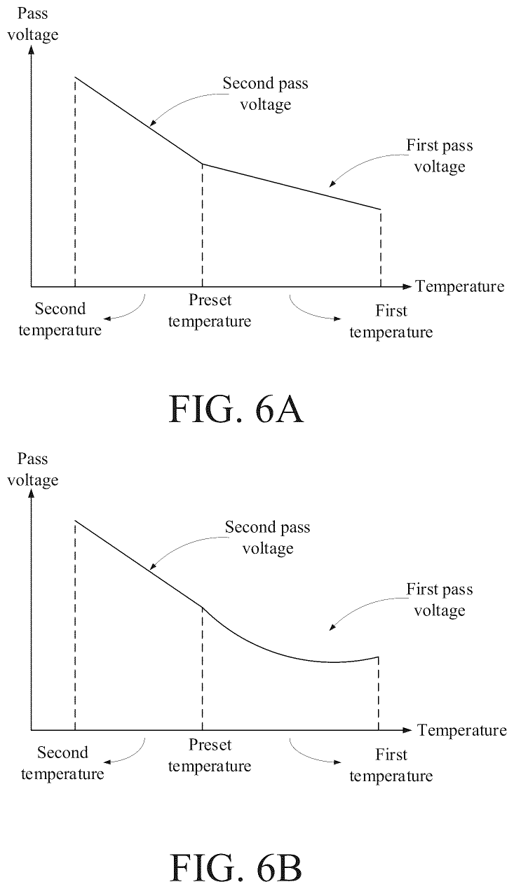

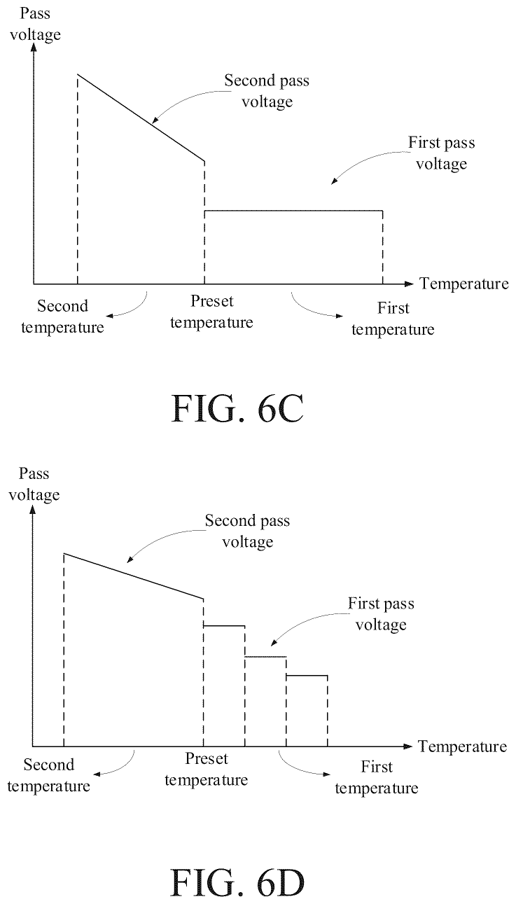

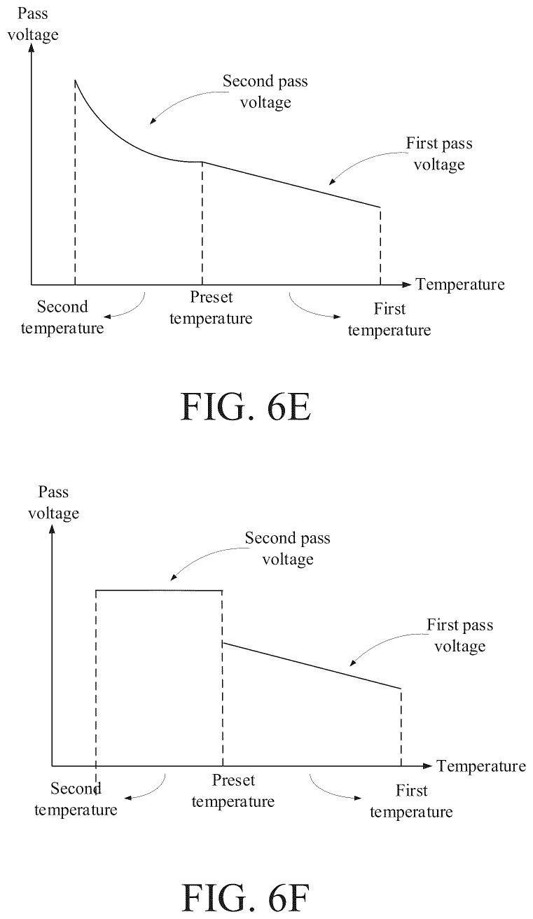

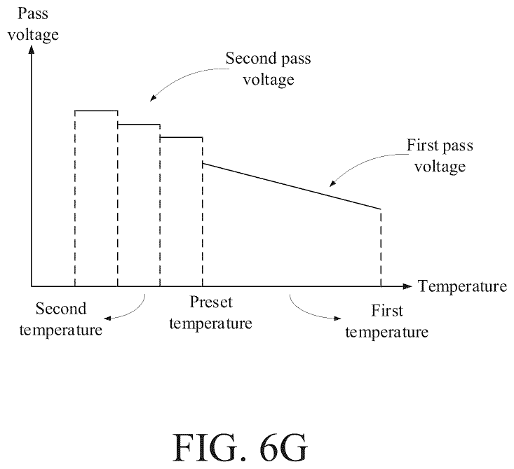

FIG. 5 is a schematic diagram of a selected word line and unselected word lines of a memory string in a memory device during a read operation provided by examples of the present application. FIGS. 6A-6G are schematic diagrams of curves between temperatures and pass voltages provided by some examples of the present application. For example, FIG. 5 may be an example of one of a plurality of memory strings in the memory block BLK shown in FIG. 2.

It is to be noted that, a top select transistor, a top select line, a bottom select transistor, and a bottom select line are omitted from FIG. 5. In the case where the above devices are comprised, during the read operation, the bottom select transistor may be controlled to be turned on through the bottom select line and the top select transistor may be controlled to be turned on through the top select line.

As shown in FIGS. 1 and 5, in the memory array 110, one memory string (e.g., a selected memory string Sel Str) may comprise a plurality of memory cells. Each of the plurality of memory cells is coupled with one word line (e.g., Unsel WL0-WLn−1, Sel WLn, and Unsel WLn+1). The word line Sel WLn represents a selected word line during the read operation, the word lines Unsel WL0-WLn−1 and Unsel WLn+1 represent unselected word lines during the read operation. The peripheral circuit 120 is configured to apply a read voltage to a selected first word line (e.g., the word line Sel WLn) of the plurality of word lines, apply a first pass voltage to unselected second word lines (e.g., the word lines Unsel WL0-WLn−1 and Unsel WLn+1) of the plurality of word lines in response to determining that a working temperature is a first temperature, and apply a second pass voltage to the second word lines (e.g., the word lines Unsel WL0-WLn−1 and Unsel WLn+1) in response to determining that the working temperature is a second temperature. Wherein the first temperature is greater than the second temperature, and the first pass voltage is less than the second pass voltage.

In some implementations, the working temperature may be obtained through detection by a temperature recognition circuit. The temperature recognition circuit may be integrated into the logic control circuit 125, or may be disposed separately and coupled with the logic control circuit 125. For example, the temperature recognition circuit may detect the working temperature of the memory device in real time and take it as the first temperature or the second temperature. The temperature recognition circuit may also send a detection signal to the logic control circuit 125. The detection signal carries a working temperature value of the memory cell. The memory device comprises a temperature and pass voltage corresponding table that comprises a plurality of temperature values and a plurality of pass voltages corresponding to the plurality of temperature values one by one. In the temperature and pass voltage corresponding table, the temperature value may be set in an increasing manner, and the pass voltage needs to be set in a decreasing manner. Of course, the temperature value may be also set in a decreasing manner, while the pass voltage needs to be set in an increasing manner, That is, a high temperature value corresponds to a low pass voltage value, and a low temperature value corresponds to a high pass voltage value.

In some implementations, the logic control circuit 125, in response to the detection signal sent by the temperature recognition circuit, looks up the corresponding pass voltage in the temperature and pass voltage corresponding table according to the temperature value carried in the detection signal to determine the pass voltage to be applied to the second word lines (e.g., the word lines Unsel WL0-WLn−1 and Unsel WLn+1 in FIG. 5). For example, if the temperature value carried in the detection signal has a corresponding value in the temperature and pass voltage corresponding table, the pass voltage value to be applied to the second word line can be directly obtained. If the temperature value carried in the detection signal has no corresponding value in the temperature and pass voltage corresponding table, the pass voltage value to be applied to the second word line can be indirectly obtained by an interpolation method, etc. For example, the pass voltage value corresponding to the temperature value may be estimated from pass voltage values corresponding to temperature values adjacent to that temperature value.

In some implementations, the first temperature may be greater than a preset temperature, and the second temperature may be less than the preset temperature. The preset temperature may be set according to the highest working temperature and the lowest working temperature of the memory cell detected by the temperature recognition circuit. For example, the preset temperature may select a temperature value between the highest working temperature and the lowest working temperature of the memory cell. For example, the preset temperature may be 0° C.

In some implementations, the temperature recognition circuit may detect the working temperature of the memory cell in real time and compare the detected working temperature with the preset temperature. If the detected working temperature is greater than the preset temperature, it is determined that the working temperature is the first temperature, and output a first detection signal to the logic control circuit 125 in the peripheral circuit 120. If the detected working temperature is less than the preset temperature, it is determined that the working temperature is the second temperature, and output a second detection signal to the logic control circuit 125 in the peripheral circuit 120.

In some implementations, the first pass voltage decreases as the first temperature increases. For example, within a first temperature range, the first pass voltage may decrease linearly or non-linearly as the first temperature increases. For example, as shown in FIG. 6A, within the first temperature range, the first pass voltage decreases linearly at a first slope as the first temperature increases. In this case, the control difficulty can be reduced. For another example, as shown in FIG. 6B, within the first temperature range, the first pass voltage decreases non-linearly as the first temperature increases. For another example, as shown in FIG. 6D, within the first temperature range, the first pass voltage decreases in a step manner as the first temperature increases. In some other implementations, as shown in FIG. 6C, within the first temperature range, the first pass voltage may be a constant as the first temperature increases.

In some implementations, the second pass voltage may decrease as the second temperature increases. For example, within a second temperature range, the second pass voltage may decrease linearly or non-linearly as the second temperature increases. For example, as shown in FIG. 6A, within the second temperature range, the second pass voltage decreases linearly at a second slope as the second temperature increases. In this case, the control difficulty can be reduced. For another example, as shown in FIG. 6E, within the second temperature range, the second pass voltage decreases non-linearly as the second temperature increases. For another example, as shown in FIG. 6G, the second pass voltage decreases in a step manner as the second temperature increases. In some other implementations, as shown in FIG. 6F, within the second temperature range, the second pass voltage may be a constant as the second temperature increases.

In some implementations, as shown in FIG. 6A, within the first temperature range, the first pass voltage decreases at a first slope as the first temperature increases. Within the second temperature range, the second pass voltage decreases at a second slope as the second temperature increases. The second slope is different from the first slope. For example, the first slope may be greater than the second slope. For another example, the first slope may be less than the second slope. In this implementation, since the high temperature (e.g., the first temperature range) and the low temperatures (e.g., the second temperature range) have different effects on the drift degree and the sense margin, the difference between the first slope and the second slope can balance the drift degree and the sense margin at the high and low temperatures, reduce the read disturbance and improve the read accuracy.

It is to be noted that, as shown in FIGS. 6A-6G, the minimum value of the first pass voltage is not less than a value of a preset pass voltage. Wherein the minimum value of the first pass voltage corresponds to a maximum temperature value of the first temperature. The preset pass voltage is determined according to the programmed state of the memory cell and the threshold voltage drift caused by the read voltage. For example, as shown in FIG. 4, the preset pass voltage needs to be greater than a maximum threshold voltage value within a threshold voltage range of the programmed state P7 after the maximum drift.

In some implementations, as shown in FIGS. 1, 2 and 5, the memory array 110 further comprises a plurality of bit lines BL and a source line SL. A selected memory string Sel Str where a selected memory cell is located may be coupled with one of the plurality of bit lines BL. For example, this bit line may be referred to as a selected bit line Sel BL. The selected memory string Sel Str where the selected memory cell Sel MC is located may be also coupled with the source line SL. The peripheral circuit 120 may be also configured to: apply a first bias voltage V_{bias1} to the selected bit line Sel BL of the plurality of bit lines BL, and apply a second bias voltage V_{bias2} to the source line SL. Wherein the first bias voltage V_{bias1} is different from the second bias voltage V_{bias2}. For example, the first bias voltage V_{bias1} may be greater than 0, and the second bias voltage V_{bias2} may be equal to 0. In an example, an inhibit voltage V_{inhibit} may be applied to the bit line coupled with an unselected memory string where an unselected memory cell is located. For example, the inhibit voltage V_{inhibit} and the second bias voltage V_{bias2} may be the same, such that a voltage difference is not generated by the unselected memory strings.

In some implementations, the read voltage may be less than the first pass voltage, and the read voltage may be less than the second pass voltage to ensure that the unselected memory cell is turned on during the read operation. For example, both the first pass voltage and the second pass voltage are greater than the read voltage, such that the unselected memory cell in the selected memory string Sel Str is turned on, and the storage state of the selected memory cell Sel MC is determined using a magnitude of the current flowing through the selected memory string Sel Str.

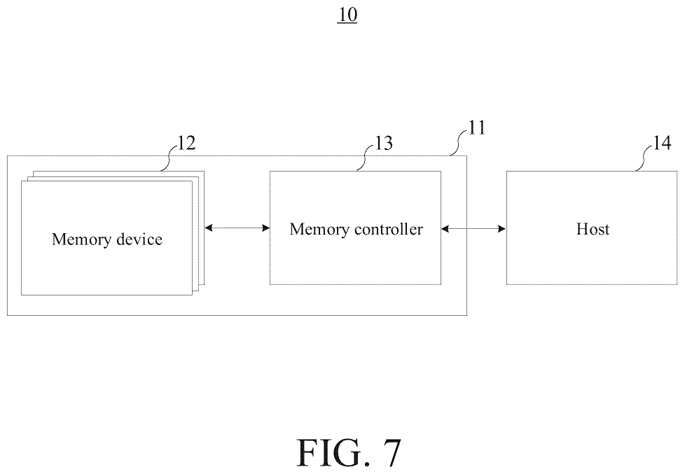

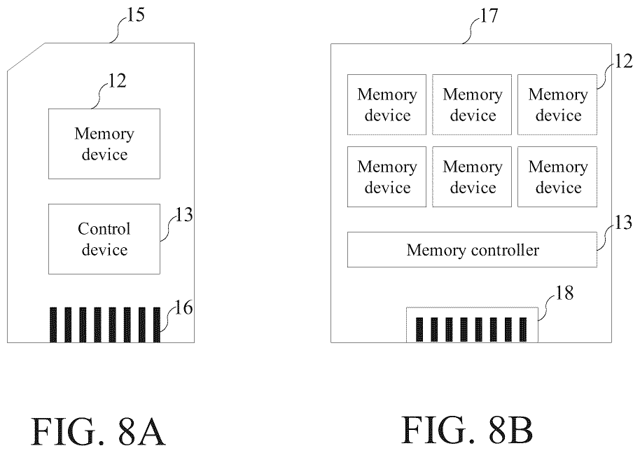

Examples of the present application further provide a memory system. FIG. 7 is a schematic block diagram of a system having a memory system provided by examples of the present application. FIGS. 8A and 8B are schematic block diagrams of a memory system provided by examples of the present application.

As shown in FIG. 7, the system 10 may be a mobile phone, a desktop computer, a laptop computer, a tablet computer, a vehicle computer, a gaming console, a printer, a positioning device, a wearable electronic device, a smart sensor, a virtual reality (VR) device, an augmented reality (AR) device, or any other suitable electronic devices having memory systems 11 therein. As shown in FIG. 7, the system 10 may comprise a host 14 and a memory system 11. The memory system 11 has one or more memory devices 12 and a memory controller 13. The host 14 may be a processor of an electronic device, such as a central processing unit (CPU), or a system on chip (SoC), such as an application processor (AP). The host 14 may be configured to send or receive data to or from the memory device 12.

The memory device 12 may be implemented as the memory device mentioned in any of the implementations above. According to some implementations, the memory controller 13 is coupled to the memory device 12 and the host 14, and configured to control the memory device 12. The memory controller 13 may manage data stored in the memory device 12 and communicate with the host 14. In some implementations, the memory controller 13 is designed for operating in a low duty-cycle environment, such as a secure digital (SD) card, a compact flash (CF) card, a universal serial bus (USB) flash drive, or other media for use in electronic devices, such as personal computers, digital cameras, and mobile phones, etc. In some implementations, the memory controller 13 may be designed for operating in a high duty-cycle environment, such as a solid state drive (SSD) or an embedded multi-media card (eMMC) used as data memory devices for mobile devices, such as a smartphone, a tablet computer, and a laptop computer, etc., and an enterprise memory array. The memory controller 13 may be configured to control operations of the memory device 12, such as read, erase, and program operations. The memory controller 13 may be also configured to manage various functions with respect to data stored or to be stored in the memory device 12, including, but not limited to, bad block management, garbage collection, logical to physical address conversion, wear leveling, etc. In some implementations, the memory controller 13 is further configured to process error correction codes (ECCs) associated with data read from or written to the memory device 12. Any other suitable function may be also executed by the memory controller 13, such as formatting the memory device 12. The memory controller 13 may communicate with an external device (e.g., the host 84) according to a specific communication protocol. For example, the memory controller 13 may communicate with the external device through at least one of various interface protocols, such as a USB protocol, an MMC protocol, a Peripheral Component Interconnect (PCI) protocol, a PCI-express (PCI-E) protocol, an Advanced Technology Attachment (ATA) protocol, a serial ATA protocol, a parallel ATA protocol, a Small Computer Small Interface (SCSI) protocol, an Enhanced Small Disk Interface (ESDI) protocol, an Integrated Drive Electronics (IDE) protocol, and a Firewire protocol, etc.

The memory controller 13 and one or more memory devices 12 may be integrated into various types of memory systems, for example, be included in the same package such as a universal flash storage (UFS) package or an eMMC package. That is to say, the memory system 11 may be implemented and packaged into different types of end electronic products. In an example as shown in FIG. 8A, the memory controller 13 and a single memory device 12 may be integrated into a memory card 15. The memory card 15 may comprise a PC card (Personal Computer Memory Card International Association (PCMCIA)), a CF card, a Smart Media (SM) card, a memory stick, a multimedia card (MMC, RS-MMC, MMCmicro), an SD card (SD, miniSD, microSD, SDHC), a UFS, etc. The memory card 15 may further comprise a memory card connector 16 that couples the memory card 15 with a host (e.g., the host 14 in FIG. 7). In another example as shown in FIG. 8B, the memory controller 13 and the plurality of memory devices 12 may be integrated into the SSD 17. The SSD 17 may further comprise an SSD connector 18 that couples the SSD 17 with a host (e.g., the host 14 in FIG. 7). In some implementations, the storage capacity and/or operating speed of the SSD 17 are higher than those of the memory card 15.

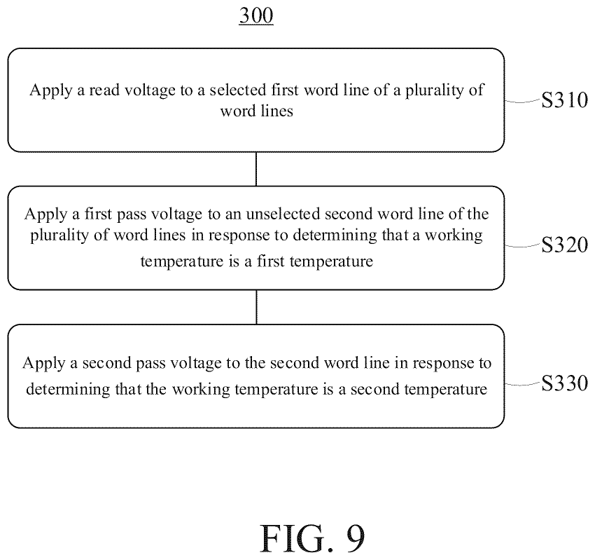

Examples of the present application further provide a method of operating a memory device. FIG. 9 is a flow diagram of a method of operating a memory device provided by examples of the present application. For example, the operation method (hereinafter referred to as the operation method) 300 of the memory device may be performed by the peripheral circuit 120 shown in FIG. 1.

As shown in FIG. 9, the operation method 300 may comprises:
S310, applying a read voltage to a selected first word line of a plurality of word lines;
S320, applying a first pass voltage to an unselected second word line of the plurality of word lines in response to determining that a working temperature is a first temperature; and
S330, applying a second pass voltage to the second word line in response to determining that the working temperature is a second temperature.

Wherein the first temperature is greater than the second temperature, and the first pass voltage is less than the second pass voltage.

According to the operation method provided by the examples of the present application, different pass voltages are applied to the word lines coupled with the unselected memory cells during execution of the read operation at different working temperatures. When the working temperature is higher, a lower pass voltage is applied, and when the working temperature is lower, a higher pass voltage is applied. For example, a higher working temperature correspond to a lower pass voltage, and a lower working temperature correspond to a higher pass voltage. When the working temperature is higher, the lower pass voltage is applied correspondingly to enable to greatly reduce high temperature read interference and ensure that the sense margin will not be excessively reduced. When the working temperature is lower, the higher pass voltage is applied correspondingly, which can reduce the difference in sense margin between the high and low temperatures, ensure the read accuracy, and have no obvious influence on the read disturbance.

In some implementations, operation S320 may comprise: determining the first pass voltage according to the first temperature in response to determining that the working temperature is the first temperature, and applying the first pass voltage to the second word line. Operation S330 may comprise: determining the second pass voltage according to the second temperature in response to determining that the working temperature is the second temperature, and applying the second pass voltage to the second word line. Since the implementations of the determining the first pass voltage according to the first temperature and determining the second pass voltage according to the second temperature have been described correspondingly above, the present application will no longer repeat them here.

In some implementations, the first temperature may be greater than a preset temperature, and the second temperature may be less than the preset temperature. For example, the first temperature may be a temperature value within the first temperature range greater than the preset temperature, and the second temperature may be a temperature value within the second temperature range less than the preset temperature. Since the setting manner of the preset temperature has been described correspondingly above, the present application will no longer repeat it here.

In some implementations, in the case where the working temperature of the memory cell is determined as a temperature value within the first temperature range, the first pass voltage decreases as the first temperature increases. For example, the first pass voltage decreases linearly at a first slope as the first temperature increases. In this case, the control difficulty can be reduced. For another example, the first pass voltage decreases non-linearly as the first temperature increases. For another example, the first pass voltage decreases in a step manner as the first temperature increases. In some other implementations, in the case where the working temperature of the memory cell is determined as a temperature value within the first temperature range, the first pass voltage may be a constant as the first temperature increases.

In some implementations, in the case where the working temperature of the memory cell is determined as a temperature value within the second temperature range, the second pass voltage decreases as the second temperature increases. For example, the second pass voltage decreases linearly at a second slope as the second temperature increases. In this case, the control difficulty can be reduced. For another example, the second pass voltage decreases non-linearly as the second temperature increases. For another example, the second pass voltage decreases in a step manner as the second temperature increases. In some other implementations, in the case where the working temperature of the memory cell is determined as a temperature value within the second temperature range, the second pass voltage may be a constant as the second temperature increases.

In some implementations, in the case that the working temperature of the memory cell is a temperature value within the first temperature range, the first pass voltage decreases linearly at a first slope as the first temperature increases, and the second pass voltage decreases linearly at a second slope as the second temperature increases. Wherein the first slope is different from the second slope. In this case, the linear decreasing manner can reduce the control difficulty, and the difference between the first slope and the second slope can balance the drift degree and the sense margin at the high and low temperatures, reduce the read disturbance and improve the read accuracy.

In some implementations, the operation method 300 may further comprise: applying a first bias voltage to a selected bit line of a plurality of bit lines, and applying a second bias voltage to a source line. Wherein the first bias voltage is different from the second bias voltage.

In some implementations, the read voltage is less than the first pass voltage, and the read voltage is less than the second pass voltage, to ensure that the unselected memory cell is turned on during the read operation.

The above descriptions are merely the descriptions of implementations of the present application and technical principles used. Those skilled in the art should understand that, the protection scope of the present application is not limited to the technical solutions formed by a particular combination of the above technical features and meanwhile should also encompass other technical solutions formed by any combination of the above technical features or equivalent features thereof without departing from the technical conception, for example, technical solutions formed by interchanging the above features with the technical features having similar functions as disclosed (but not limited thereto) in the present application.

What is claimed is:

1. A memory device, comprising:
a memory array comprising a plurality of memory cells and a plurality of word lines coupled with the plurality of memory cells; and
a peripheral circuit coupled with the memory array and configured to:
apply a read voltage to a selected first word line of the plurality of word lines;
apply a first pass voltage to an unselected second word line of the plurality of word lines, in response to determining that a working temperature of the memory device is a first temperature; and
apply a second pass voltage to the second word line in response to determining that the working temperature is a second temperature,
wherein the first temperature is greater than the second temperature, and the first pass voltage is less than the second pass voltage.

2. The memory device of claim 1, wherein the peripheral circuit is further configured to:
in response to determining that the working temperature is the first temperature, determine the first pass voltage according to the first temperature, and apply the first pass voltage to the second word line; and
in response to determining that the working temperature is the second temperature, determine the second pass voltage according to the second temperature, and apply the second pass voltage to the second word line.

3. The memory device of claim 2, wherein the first temperature is greater than a preset temperature, and the second temperature is less than the preset temperature.

4. The memory device of claim 3, wherein the first pass voltage decreases as the first temperature increases.

5. The memory device of claim 4, wherein the first pass voltage decreases linearly at a first slope as the first temperature increases.

6. The memory device of claim 4, wherein the first pass voltage decreases non-linearly as the first temperature increases.

7. The memory device of claim 4, wherein the second pass voltage decreases as the second temperature increases.

8. The memory device of claim 5, wherein the second pass voltage decreases at a second slope as the second temperature increases, and the first slope is different from the second slope.

9. The memory device of claim 1, wherein the memory array further comprises a plurality of bit lines coupled with the plurality of memory cells, and a source line, wherein the source line is coupled with the plurality of memory cells, and the peripheral circuit is further configured to:
apply a first bias voltage to a selected bit line of the plurality of bit lines; and
apply a second bias voltage to the source line, wherein the first bias voltage is different from the second bias voltage.

10. The memory device of claim 1, wherein the read voltage is less than the first pass voltage, and the read voltage is less than the second pass voltage.

11. A memory system, comprising:
a memory device, comprising:
a memory array comprising a plurality of memory cells and a plurality of word lines coupled with the plurality of memory cells; and
a peripheral circuit coupled with the memory array and configured to:
apply a read voltage to a selected first word line of the plurality of word lines;
apply a first pass voltage to an unselected second word line of the plurality of word lines, in response to determining that a working temperature of the memory device is a first temperature; and
apply a second pass voltage to the second word line in response to determining that the working temperature is a second temperature,
wherein the first temperature is greater than the second temperature, and the first pass voltage is less than the second pass voltage; and
a memory controller coupled with the memory device and configured to control the memory device.

12. A method of operating a memory device, wherein the memory device comprises a plurality of memory cells and a plurality of word lines, the memory cells coupled with the word lines, the method comprising:
applying a read voltage to a selected first word line of the plurality of word lines;
applying a first pass voltage to an unselected second word line of the plurality of word lines, in response to determining that a working temperature of the memory device is a first temperature; and
applying a second pass voltage to the second word line in response to determining that the working temperature is a second temperature,
wherein the first temperature is greater than the second temperature, and the first pass voltage is less than the second pass voltage.

13. The method of claim 12, wherein applying the first pass voltage comprises:
in response to determining that the working temperature is the first temperature, determining the first pass voltage according to the first temperature, and applying the first pass voltage to the second word line, and
wherein applying the second pass voltage comprises:
in response to determining that the working temperature is the second temperature, determining the second pass voltage according to the second temperature, and applying the second pass voltage to the second word line.

14. The method of claim 13, wherein the first temperature is greater than a preset temperature, and the second temperature is less than the preset temperature.

15. The method of claim 14, wherein the first pass voltage decreases as the first temperature increases.

16. The method of claim 15, wherein the first pass voltage decreases linearly at a first slope as the first temperature increases.

17. The method of claim 15, wherein the first pass voltage decreases non-linearly as the first temperature increases.

18. The method of claim 15, wherein the second pass voltage decreases as the second temperature increases.

19. The method of claim 16, wherein the second pass voltage decreases linearly at a second slope as the second temperature increases, and the first slope is different from the second slope.

20. The method of claim 12, wherein the memory device further comprises a plurality of bit lines coupled with the memory cells, and a source line, wherein the source line is coupled with the memory cells, the method further comprising:
applying a first bias voltage to a selected bit line of the plurality of bit lines; and
applying a second bias voltage to the source line, wherein the first bias voltage is different from the second bias voltage.
